(19) United States
(12) Patent Application Publication
(10) Pub. No.: US 2026/0341575 A1
(43) Pub. Date: Oct. 29, 2026

(54) DIRECT CURRENT RESISTANCE (DCR) OPTIMIZED INDUCTOR FOR VERTICAL POWER APPLICATIONS

(71) Applicant: Flex Ltd., Singapore (SG)

(72) Inventor: Mikael H. Appelberg, Farjestaden (SE)

(21) Appl. No.: 19/569,505

(22) Filed: Mar. 17, 2026

Related U.S. Application Data
(60) Provisional application No. 63/773,188, filed on Mar. 17, 2025.

(51) Int. Cl. H01F 27/24; H01F 27/28; H05K 1/181

(52) U.S. Cl. CPC H01F 27/24; H01F 27/28; H05K 1/181; H05K 2201/1003

(57) ABSTRACT

Embodiments of the disclosure provide an inductor targeted for vertical power applications. According to one embodiment, an inductor can comprise at least one u-shaped TLVR conductor, at least one straight power conductor adjacent to the TLVR conductor, and a magnetic material encapsulating the at least one TLVR conductor and the at least one power conductor. The power conductor can extend beyond the TLVR conductor on a first side of the inductor. A connection to the power conductor can be made on the first side of the inductor, and a connection to the TLVR conductor can be made on a second side of the inductor opposite the first side.

### CROSS REFERENCE TO RELATED APPLICATION

The present application claims the benefits of and priority, under 35 U.S.C. § 119(e), to U.S. Provisional Application Number 63/773,188 filed Mar. 17, 2025 by Appelberg and entitled “DCR Optimized Inductor for Vertical Power Applications” of which the entire disclosure is incorporated herein by reference for all purposes.

### FIELD OF THE DISCLOSURE

Embodiments of the present disclosure relate generally to methods and systems for power inductors and more particularly to an inductor optimized for Trans-Inductor Voltage Regulation (TLVR).

### BRIEF SUMMARY

Embodiments of the disclosure provide an inductor targeted for vertical power applications. In this application space an inductor should be connected between two PCB boards, have a very low DC resistance, have Trans-Inductor Voltage Regulator (TLVR) integrated, allow capacitors to be placed underneath it, minimize the volume required for the inductor, and support some type of bonding (glue) between the boards. According to one embodiment, an inductor can comprise at least one u-shaped TLVR conductor, at least one straight power conductor adjacent to the TLVR conductor, and a magnetic material encapsulating the at least one TLVR conductor and the at least one power conductor. The power conductor can extend beyond the TLVR conductor on a first side of the inductor. A connection to the power conductor can be made on the first side of the inductor, and a connection to the TLVR conductor can be made on a second side of the inductor opposite the first side.

The inductor can further comprise a bonding area proximate to the power conductor on the first side of the inductor and a bonding area proximate to the TLVR conductor on the second side of the inductor. The power conductor and TLVR conductor can be positioned to create a flux cancellation zone between the power conductor and TLVR conductor. In some cases, one or more capacitors can be disposed adjacent to the first side of the inductor. The inductor can comprise a single-phase inductor, a two-phase inductor, a four-phase inductor, a six-phase inductor, or any number of phases which is a multiple of two.

According to another embodiment, a power module can comprise a first Printed Circuit Board (PCB), a second PCB positioned parallel to the first PCB, and an inductor disposed between and coupled with the first PCB and the second PCB. The inductor can comprise at least one u-shaped Trans-inductor Voltage Regulator (TLVR) conductor, at least one straight power conductor adjacent to the TLVR conductor, and a magnetic material encapsulating the at least one TLVR conductor and the at least one power conductor. The power conductor can extend beyond the TLVR conductor on a first side of the inductor adjacent to the first PCB and a connection between the power conductor and the first PCB can be made on the first side of the inductor. A connection between the TLVR conductor and the second PCB can be made on a second side of the inductor opposite the first side.

The power module can further comprise a bonding area proximate to the power conductor on the first side of the inductor and a bonding area proximate to the TLVR conductor on the second side of the inductor. The inductor can be bonded to the first PCB by an adhesive disposed on the bonding area on the first side of the inductor and bonded to the second PCB by an adhesive disposed on the bonding area on the second side of the inductor. The power conductor and TLVR conductor can be positioned to create a flux cancellation zone between the power conductor and TLVR conductor. In some cases, one or more capacitors can be disposed adjacent to the first side of the inductor. The inductor can comprise a single-phase inductor, a two-phase inductor, a four-phase inductor, a six-phase inductor, or any number of phases which is a multiple of two. The power module can comprise, but is not limited to, a vertical power module.

### BRIEF DESCRIPTION OF THE DRAWINGS

FIG. 1 illustrates an example of a prior art four-phase inductor.

FIG. 2 illustrates windings of the four-phase inductor of FIG. 1.

FIGS. 3A and 3B illustrate another example of a prior art four-phase inductor.

FIG. 4 illustrates windings of the four-phase inductor of FIGS. 3A and 3B.

FIG. 5 illustrates an example of a prior art two-phase inductor.

FIG. 6 illustrates windings of the two-phase inductor of FIG. 5.

FIGS. 7A and 7B illustrate an inductor according to one embodiment of the present disclosure.

FIG. 8 illustrates windings of the inductor of FIGS. 7A and 7B.

FIGS. 9A and 9B illustrate an inductor according to another embodiment of the present disclosure.

FIGS. 10A and 10B illustrate an inductor according to yet another embodiment of the present disclosure.

FIGS. 11A and 11B illustrate an inductor according to still another embodiment of the present disclosure.

FIG. 12 illustrates a power module incorporating an inductor according to embodiments of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

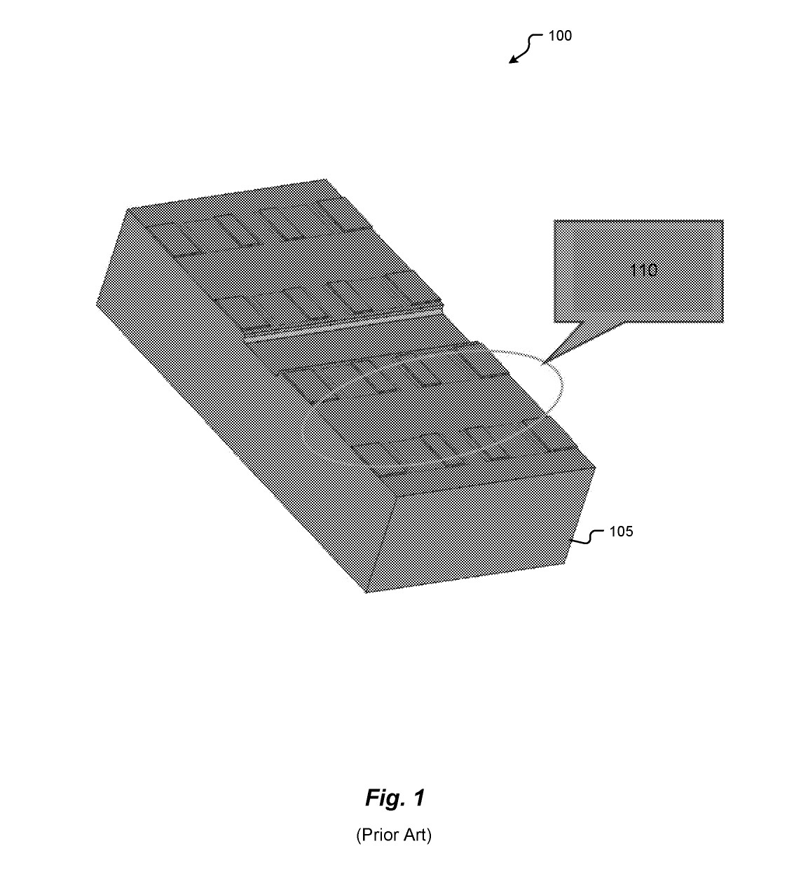

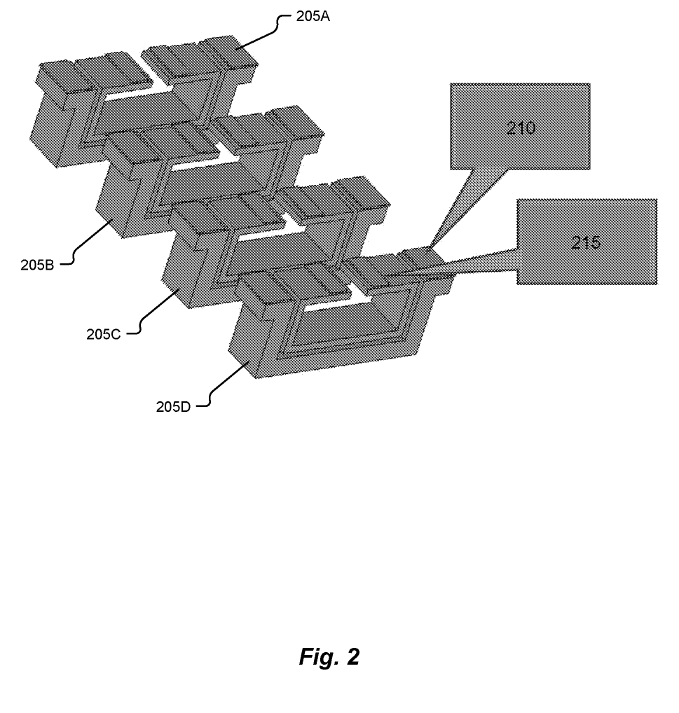

FIG. 1 illustrates an example of a prior art four-phase inductor 100. FIG. 2 illustrates windings 205A-205D of the four-phase inductor of FIG. 1. As illustrated in FIG. 1, the inductor comprises a magnetic molding compound which surrounds the inductors 205A-205D. Also as illustrated in FIG. 1, a flux cancellation zone 110 is created between windings. As known in the art, flux cancellation zone can be created between adjacent conductors in a magnetic material when the fields of the conductors flow in opposite directions. When the conductors are positioned so that their fields overlap, the result is that these field cancel each other and eliminate net magnetic flux in that are of the inductor.

As illustrated in FIG. 2, each winding 205A-205D comprises a power conductor 210 and a Trans-inductor Voltage Regulator (TLVR) conductor 215. However, this four-phase inductor 100 doesn’t offer a path between two boards for the power winding, nor a low Direct Current Resistance (DCR) or an efficient way to use the component to bond two boards together.

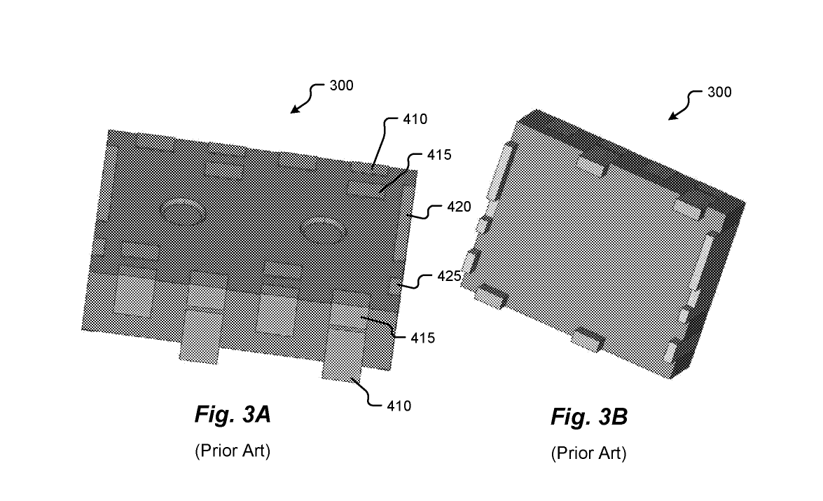

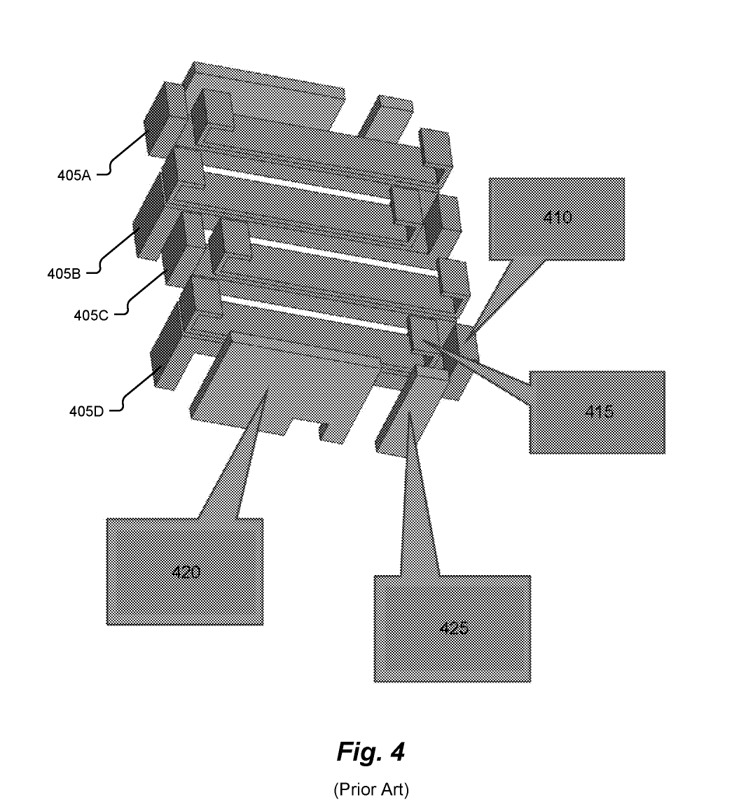

FIGS. 3A illustrates a top view and FIG. 3B illustrates a bottom view of another example of a prior art four-phase inductor 300. FIG. 4 illustrates windings 405A-405D of the four-phase inductor of FIGS. 3A and 3B. As shown here, each winding 405A-405D comprises a power conductor 410 and a TLVR conductor 415. The inductor 300 can also include a ground connection 420 and a TLVR interconnect 425. This four-phase inductor 300 offers a path between two boards for the power winding, but not a low DCR or an efficient way to use the component to bond two boards together.

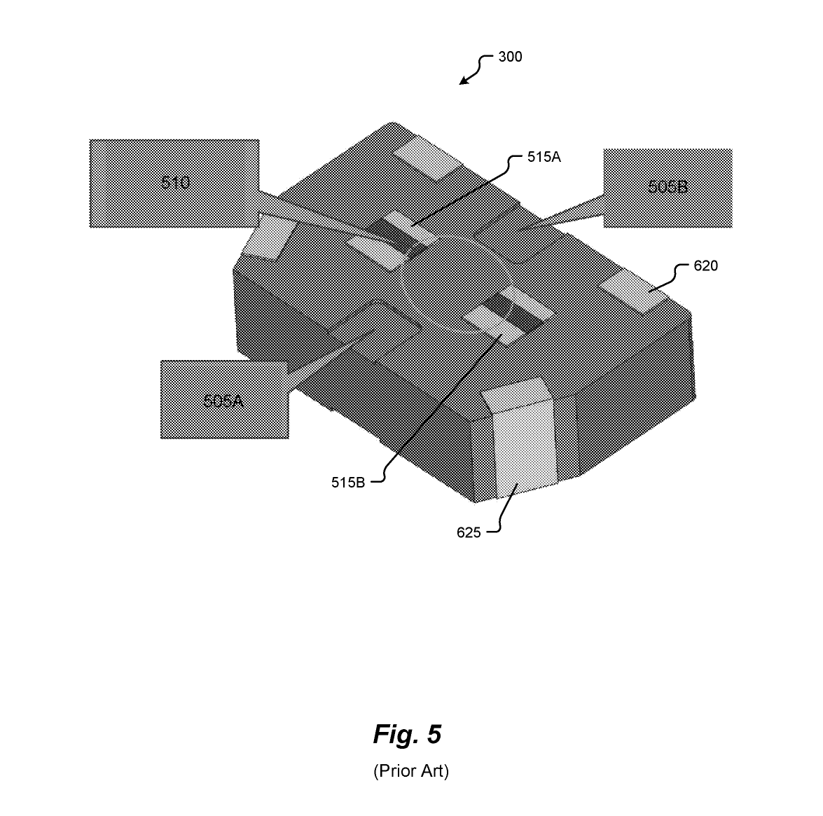

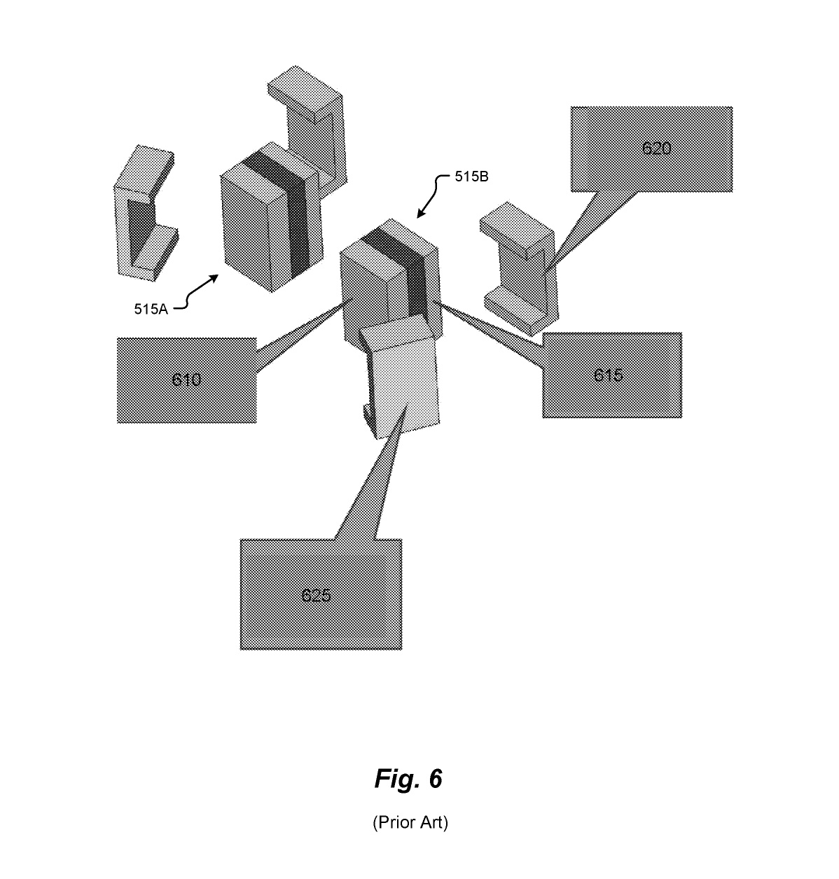

FIG. 5 illustrates an example of a prior art two-phase inductor 500. As shown here, the inductor 500 comprises areas 505A and 505B for glue or other adhesives and a flux cancellation zone 510 created between the windings 515A and 515B. FIG. 6 illustrates windings 515A and 515B of the two-phase inductor of FIG. 5. As shown, each winding 515A and 515B comprises a power conductor 610 and a TLVR conductor 615. The inductor 500 can also include a ground connection 625 and the TLVR return 620 (the return to the top side). This two-phase inductor offers a path between two boards for the power winding, a low DCR and an efficient way to use the component to bond two boards together. However, it requires extra routing on the bottom board between the TLVR winding and the TLVR interconnect and it doesn’t allow capacitors to be placed underneath it.

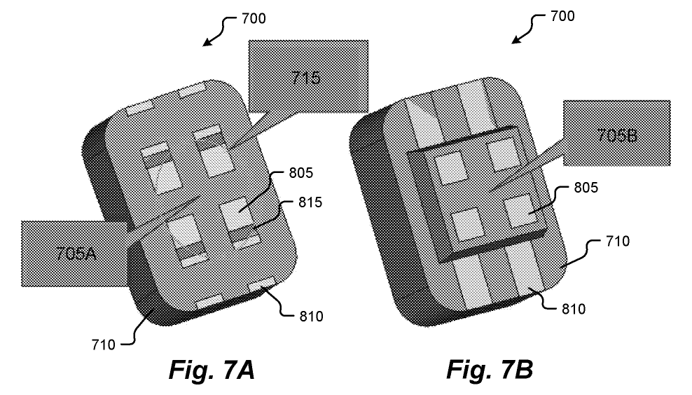

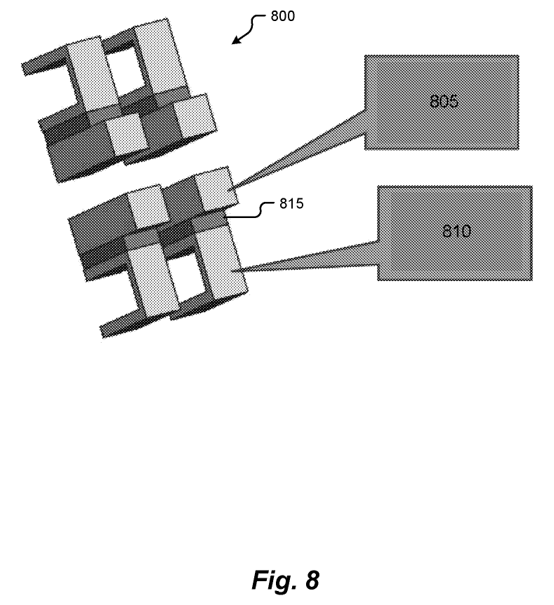

FIGS. 7A and 7B illustrate an inductor according to one embodiment of the present disclosure. More specifically, FIG. 7A illustrates a top view and FIG. 7B illustrates a bottom view of a four-phase inductor 700 according to one embodiment of the present disclosure. As illustrated here, the inductor 700 can comprise areas for glue 705 and 705B on both the top side and bottom side. FIG. 8 illustrates windings 800 of the inductor of FIGS. 7A and 7B. The windings can be encapsulated in a magnetic material 710 and a flux cancellation zone can be created between the windings. Each winding 800 can comprise power conductor and a TLVR conductor separated by an insulator 815.

As shown, the straight power conductor 805 encapsulated by the magnetic material 710 can be combined with a U-shaped TLVR conductor 810, allowing all the TLVR connections to be done on to a board on the top side of the inductor 700. The power conductor 805 can extend a distance below the TLVR conductor 810 and the magnetic material 710 on the bottom side of the inductor 700, allowing for other components to be placed beneath the inductor on a board on the bottom side of the inductor 700. To minimize the volume required the conductors 805 and 810 can be placed so that a flux cancellation is achieved between the conductors 805, which reduces the inductor size. The area 705A and 705B between the power conductors 805 can be used for bonding between the boards.

Stated another way, an inductor 700 can comprise at least one u-shaped TLVR conductor 810, at least one straight power conductor 805 adjacent to the TLVR conductor 810, and a magnetic material 710 encapsulating the at least one TLVR conductor 810 and the at least one power conductor 805. The power conductor 805 can extend beyond the TLVR conductor 810 on a first side of the inductor 700. A connection to the power conductor 805 can be made on the first side of the inductor 700, and a connection to the TLVR conductor 810 can be made on a second side of the inductor 700 opposite the first side.

The inductor 700 can further comprise a bonding area 705B proximate to the power conductor 805 on the first side of the inductor 700 and a bonding area 705A proximate to the TLVR conductor 810 on the second side of the inductor 700. The power conductor 805 and TLVR conductor 810 can be positioned to create a flux cancellation zone 715 between the power conductor 805. In some cases, one or more capacitors can be disposed adjacent to the first side of the inductor 700. The inductor can comprise a single-phase inductor, a two-phase inductor, a four-phase inductor, or a six-phase inductor.

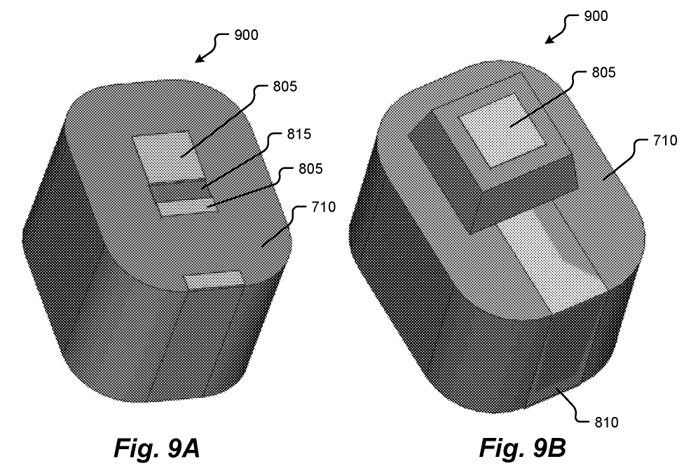

FIGS. 9A and 9B illustrate an inductor according to another embodiment of the present disclosure. More specifically, FIG. 9A illustrates a top view and FIG. 9B illustrates a bottom view of a single-phase inductor 900. As described above, the straight power conductor 805 can extend a distance below the TLVR conductor 810 and the magnetic material 710 on the bottom side of the inductor 900.

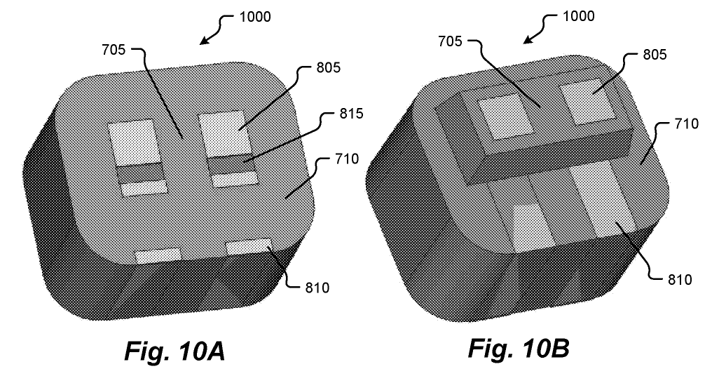

FIGS. 10A and 10B illustrate an inductor according to yet another embodiment of the present disclosure. More specifically, FIG. 10A illustrates a top view and FIG. 10B illustrates a bottom view of a two-phase inductor 1000. As described above, the straight power conductor 805 can extend a distance below the TLVR conductor 810 and the magnetic material 710 on the bottom side of the inductor 1000. To minimize the volume required the conductors 805 can be placed so that a flux cancellation is achieved between them, which reduces the inductor size. The area 705 between the power conductors 805 can be used for bonding between the boards as described above.

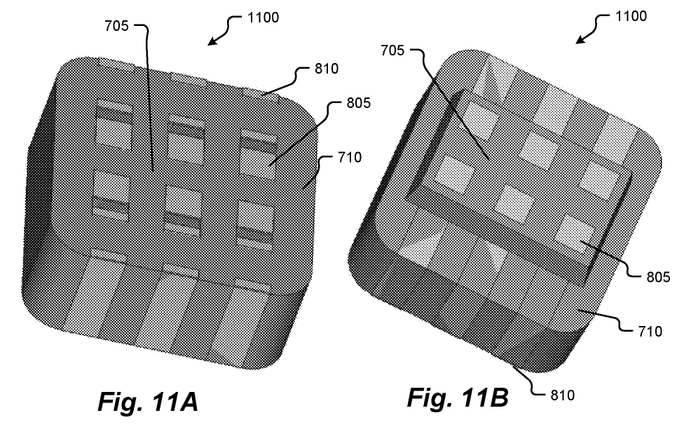

FIGS. 11A and 11B illustrate an inductor according to still another embodiment of the present disclosure. More specifically, FIG. 11A illustrates a top view and FIG. 11B illustrates a bottom view of a two-phase inductor 1100. As described above, the straight power conductor 805 can extend a distance below the TLVR conductor 810 and the magnetic material 710 on the bottom side of the inductor 1100. To minimize the volume required the conductors 805 can be placed so that a flux cancellation is achieved between the conductors 805, which reduces the inductor size. The area 705 between the power conductors 805 can be used for bonding between the boards as described above.

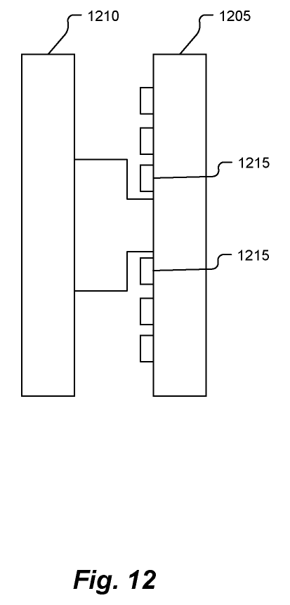

FIG. 12 illustrates a power module incorporating an inductor according to embodiments of the present disclosure. As illustrated in this example, a power module 1200 can comprise a first Printed Circuit Board (PCB) 1205, a second PCB 1210 positioned parallel to the first PCB 1205, and an inductor 700 as described above disposed between and coupled with the first PCB 1205 and the second PCB 1210. As described, the inductor 700 can comprise at least one u-shaped TLVR conductor 810, at least one straight power conductor 805 adjacent to the TLVR conductor 810, and a magnetic material 710 encapsulating the at least one TLVR conductor 810 and the at least one power conductor 805. The power conductor 805 can extend beyond the TLVR conductor 810 on a first side of the inductor 700 adjacent to the first PCB 1205 and a connection between the power conductor 805 and the first PCB 1205 can be made on the first side of the inductor 705. A connection between the TLVR conductor 810 and the second PCB 1210 can be made on a second side of the inductor 705 opposite the first side.

The power module 1200 can further comprise a bonding area 705B proximate to the power conductor 805 on the first side of the inductor 700 and a bonding area 705A proximate to the TLVR conductor 810 on the second side of the inductor 700. The inductor 700 can be bonded to the first PCB 1205 by an adhesive disposed on the bonding area 705B on the first side of the inductor 700 and bonded to the second PCB 1210 by an adhesive disposed on the bonding area 705A on the second side of the inductor 700. The power conductor 805 and TLVR conductor 810 can be positioned to create a flux cancellation zone 715 between the power conductors 805. In some cases, one or more capacitors 1215 can be disposed adjacent to the first side of the inductor 700. The inductor 700 can comprise a single-phase inductor, a two-phase inductor, a four-phase inductor, or a six-phase inductor. The power module 1200 can comprise, but is not limited to, a vertical power module.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. An inductor comprising:
at least one u-shaped Trans-inductor Voltage Regulator (TLVR) conductor;
at least one straight power conductor adjacent to the TLVR conductor; and
a magnetic material encapsulating the at least one TLVR conductor and the at least one power conductor, wherein the power conductor extends beyond the TLVR conductor on a first side of the inductor, wherein a connection to the power conductor is made on the first side of the inductor, and wherein a connection to the TLVR conductor is made on a second side of the inductor opposite the first side.

2. The inductor of claim 1, further comprising a bonding area proximate to the power conductor on the first side of the inductor and a bonding area proximate to the TLVR conductor on the second side of the inductor.

3. The inductor of claim 1, wherein the power conductor and TLVR conductor are positioned to create a flux cancellation zone between the power conductors.

4. The inductor of claim 1, further comprising one or more capacitors disposed adjacent to the first side of the inductor.

5. The inductor of claim 1, wherein the inductor comprises a single-phase inductor.

6. The inductor of claim 1, wherein the inductor comprises a two-phase inductor.

7. The inductor of claim 1, wherein the inductor comprises a four-phase inductor.

8. The inductor of claim 1, wherein the inductor comprises a six-phase inductor.

9. A power module comprising:
a first Printed Circuit Board (PCB);
a second PCB positioned parallel to the first PCB; and
an inductor disposed between and coupled with the first PCB and the second PCB, the inductor comprising:
at least one u-shaped Trans-inductor Voltage Regulator (TLVR) conductor,
at least one straight power conductor adjacent to the TLVR conductor, and
a magnetic material encapsulating the at least one TLVR conductor and the at least one power conductor, wherein the power conductor extends beyond the TLVR conductor on a first side of the inductor adjacent to the first PCB, wherein a connection between the power conductor and the first PCB is made on the first side of the inductor, and wherein a connection between the TLVR conductor and the second PCB is made on a second side of the inductor opposite the first side.

10. The power module of claim 9, further comprising a bonding area proximate to the power conductor on the first side of the inductor and a bonding area proximate to the TLVR conductor on the second side of the inductor, wherein the inductor is bonded to the first PCB by an adhesive disposed on the bonding area on the first side of the inductor and bonded to the second PCB by an adhesive disposed on the bonding area on the second side of the inductor.

11. The power module of claim 9, wherein the power conductor and TLVR conductor are positioned to create a flux cancellation zone between the power conductors.

12. The power module of claim 9, further comprising one or more capacitors disposed between the first side of the inductor and the first PCB.

13. The power module of claim 9, wherein the inductor comprises a single-phase inductor.

14. The power module of claim 9, wherein the inductor comprises a two-phase inductor.

15. The power module of claim 9, wherein the inductor comprises a four-phase inductor.

16. The power module of claim 9, wherein the inductor comprises a six-phase inductor.

17. The power module of claim 9, wherein the power module comprises a vertical power module.
